(19) United States
(12) Patent Application Publication
(10) Pub. No.: US 2012/0244685 A1
(43) Pub. Date: Sep. 27, 2012

(54) Manufacturing Apparatus and Method for Semiconductor Device

(75) Inventors: Kunihiko SUZUKI, Shizuoka-ken (JP); Shinichi MITANI, Shizuoka-ken (JP)

(73) Assignee: NUFLARE TECHNOLOGY, INC., Shizuoka-ken (JP)

(21) Appl. No.: 13/421,901

(22) Filed: Mar. 16, 2012

(30) Foreign Application Priority Data
Mar. 24, 2011 (JP) 2011-065746

(51) Int. Cl. H01L 21/20; C23C 16/52; C23C 16/455

(52) U.S. Cl. 438/478; 118/719; 118/699; 118/696; 257/E21.09

(57) ABSTRACT

A semiconductor manufacturing apparatus includes: a plurality of reaction chambers into which wafers are introduced and deposition process is performed; a material gas supply mechanism that includes a plurality of material gas supply lines that respectively supply a material gas to the plurality of reaction chambers and a flow rate control mechanism that controls a flow rate of the marital gas in the material gas supply lines; a carrier gas supply mechanism that includes a plurality of carrier gas supply lines that respectively supplies a carrier gas into the plurality of reaction chambers; and a material gas switching mechanism that intermittently opens and closes the plurality of material gas supply lines respectively so that at least one of the plurality of material gas supply lines comes to be in an opened state at a same time, and sequentially switches the reaction chamber to which the material gas is supplied.

### CROSS-REFERENCE TO RELATED APPLICATION

This application is based upon and claims the benefit of priority from the prior Japanese Patent Application No. 2011-065746 filed on Mar. 24, 2011, the entire contents of which are incorporated herein by reference.

### BACKGROUND

The present invention relates to a semiconductor manufacturing apparatus and a method of manufacturing a semiconductor device that are used for example in supplying a process gas onto a semiconductor wafer to perform deposition.

For example, in an Si epitaxial growing apparatus, H₂ gas which is a carrier gas and SiH₂Cl₂ gas or SiHCl₃ gas which is a material gases are mixed, and are supplied as a process gas to a reaction chamber in which a wafer has been introduced. Then, for example, a wafer temperature is made to be at about 1100° C., and Si is epitaxially grown on the wafer by a reaction of hydrogen reduction. By so doing, an Si epitaxial film having a satisfactory film quality is formed.

At this occasion, typically a ventilation process is performed for a certain period of time so as to stabilize a flow rate of the process gas, and after the flow rate has been stabilized, it is introduced into the reaction chamber.

On the other hand, especially in forming a thick epitaxial film used for a power semiconductor and the like, performing deposition by intermittently supplying the material gas (pulse-epi) is proposed as a method to improve productivity while maintaining a high quality.

In performing the pulse-epi, ON/OFF of a material gas supply line is repeated, though, the material gas is ventilated during OFF so as to stabilize the flow rate. Due to this, there is a problem that use efficiency of the material gas decreases, and cutting cost becomes difficult.

Therefore, the present invention aims to provide a semiconductor manufacturing apparatus and a method of manufacturing a semiconductor device that can improve the productivity while maintaining the high quality of the epitaxial film and improve the use efficiency of the material gas in a semiconductor manufacturing process.

### SUMMARY

A semiconductor manufacturing apparatus of an embodiment of the present invention includes: a plurality of reaction chambers into which wafers are introduced and deposition process is performed; a material gas supply mechanism that includes a plurality of material gas supply lines that respectively supply a material gas to the plurality of reaction chambers and a flow rate control mechanism that controls a flow rate of the marital gas in the material gas supply lines; a carrier gas supply mechanism that includes a plurality of carrier gas supply lines that respectively supplies a carrier gas into the plurality of reaction chambers; and a material gas switching mechanism that intermittently opens and closes the plurality of material gas supply lines respectively so that at least one of the plurality of material gas supply lines comes to be in an opened state at a same time, and sequentially switches the reaction chamber to which the material gas is supplied.

Further, a method of manufacturing a semiconductor device of an embodiment of the present invention includes: introducing wafers into a plurality of reaction chambers; retaining the wafers respectively at predetermined positions in the plurality of reaction chambers; of among a plurality of material gas supply lines that respectively supplies a material gas and a plurality of carrier gas supply lines that respectively supplies a carrier gas into the plurality of reaction chambers, at least ventilating the material gas from the plurality of material gas supply lines; intermittently opening and closing the plurality of material gas supply lines respectively so that at least one of the plurality of material gas supply lines comes to be in an opened state at a same time and sequentially switching the reaction chamber to which the material gas is supplied; supplying a process gas in a rectified state onto the wafers retained inside the reaction chambers, the process gas including the material gas and the carrier gas; heating the wafers at a predetermined temperature; and rotating the wafers at a predetermined rotation speed.

### BRIEF DESCRIPTION OF THE DRAWINGS

FIG. 1 is a diagram showing a configuration of a multi-chamber epitaxial growth apparatus of a first embodiment;

FIG. 2 is a schematic diagram showing a structure of each reaction chamber shown in FIG. 1;

FIG. 3 is a time chart showing a pulse-epi control in the first embodiment;

FIG. 4 is a time chart showing a pulse-epi control in a second embodiment;

FIG. 5 is another time chart showing the pulse-epi control in the second embodiment;

FIG. 6 is a time chart showing a pulse-epi control in a third embodiment;

FIG. 7 is another time chart showing the pulse-epi control in the third embodiment;

FIG. 8 is a diagram showing a configuration of a multi-chamber epitaxial growth apparatus of a fourth embodiment;

FIG. 9 is a time chart showing a pulse-epi control in the fourth embodiment;

FIG. 10 is a diagram showing a configuration of a multi-chamber epitaxial growth apparatus of a fifth embodiment; and

FIG. 11 is a diagram showing a configuration of a multi-chamber epitaxial growth apparatus of a sixth embodiment.

### DETAILED DESCRIPTION

Reference will now be made in detail to the present embodiment of the invention, an example of which is illustrated in the accompanying drawings.

### First Embodiment

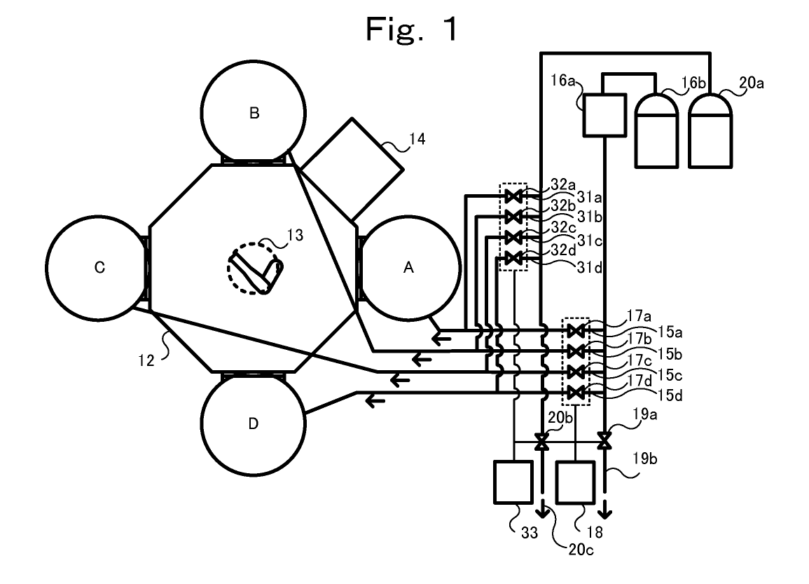

FIG. 1 shows a configuration of a multi-chamber epitaxial growth apparatus that is the semiconductor manufacturing apparatus of the present embodiment. In this example, as shown in FIG. 1, four reaction chambers A to D are provided, and these are connected to a transfer module 12. A wafer conveying robot 13 is arranged in the transfer module 12. Further, an IO module 14 for carrying in and carrying out a wafer w is connected to the transfer module 12.

The reaction chambers A to D are connected to a mass flow controller 16a that controls a flow rate of a material gas and a material gas supply unit 16b that is a supply source of the material gas via a plurality of material gas supply lines 15a to 15d that supplies the material gas such as trichlorosilane (SiHCl₃), dichlorosilane (SiH₂Cl₂) and the like. Valves 17a to 17d are connected to the material gas supply lines 15a to 15d. The valves 17a to 17d are respectively connected to a material gas switching mechanism 18 that controls ON/OFF of each valve. A material gas supply mechanism is configured of the material gas supply lines 15a to 15d, the material gas supply unit 16b, the valves 17a to 17d and the material gas switching mechanism 18. That is, the material gas supply lines 15a to 15d are controlled to be in an opened state when the valves 17a to 17d are respectively turned ON and be in a cut-off state when the valves 17a to 17d are respectively turned OFF by the material gas switching mechanism 18.

Further, a vent line 19b having a valve 19a for a material gas ventilation is connected to the material gas supply lines 15a to 15d. Note that, the valve 19a is connected to the material gas switching mechanism 18 similar to the valves 17a to 17d, and its ON/OFF switching is controlled thereby.

Further, a plurality of carrier gas supply lines 31a to 31d that supplies a carrier gas such as H₂ and the like is connected respectively to the material gas supply lines 15a to 15d at positions on a reaction chamber side than the valves 17a to 17d.

Further, the reaction chambers A to D are connected respectively to a carrier gas supply unit 20a that is a supply source of the carrier gas via the carrier gas supply lines 31a to 31d connected to the material gas supply lines 15a to 15d.

Further, valves 32a to 32d for switching a carrier gas supply by opening and closing the valves (ON/OFF) are provided on the carrier gas supply lines 31a to 31d. The valves 32a to 32d are respectively connected to a carrier gas switching mechanism 33 that controls ON/OFF of each valve. That is, the carrier gas supply lines 31a to 31d are controlled to be in an opened state when the valves 32a to 32d are respectively turned ON and be in a cut-off state when the valves 32a to 32d are respectively turned OFF by the carrier gas switching mechanism 33. A carrier gas supply mechanism is configured of the carrier gas supply unit 20a, the carrier gas supply lines 31a to 31d, the valves 32a to 32d and the carrier gas switching mechanism 33.

Further, a vent line 20c having a valve 20b for a carrier gas ventilation is connected to the carrier gas supply lines 31a to 31d. Note that, the valve 20b is connected to the carrier gas switching mechanism 33 similar to the valves 32a to 32d, and its ON/OFF switching is controlled thereby.

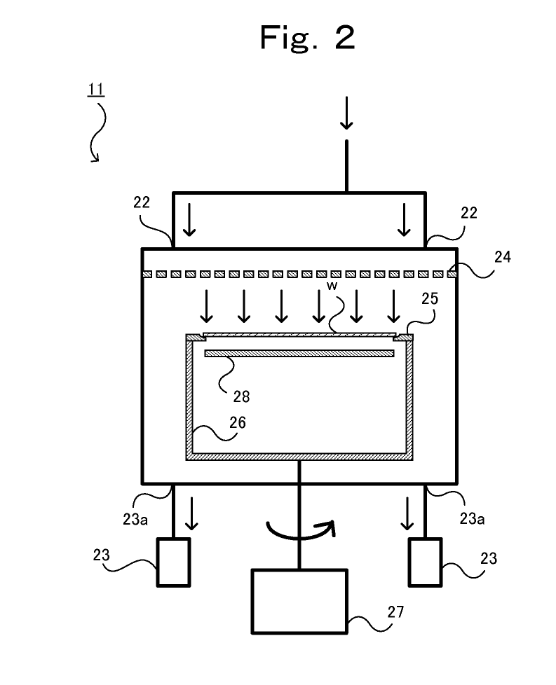

FIG. 2 shows a structure of the reaction chambers A to D. Note that, since the reaction chambers A to D have an identical structure, the reaction chambers A to D will be collectively referred to as a reaction chamber 11. As shown in FIG. 2, a wafer w of φ200 mm is introduced into the reaction chamber 11 to perform deposition process. Gas supply inlets 22 are provided at two positions at an upper portion of the reaction chamber 11 to supply a process gas including the material gas from above the wafer w. These gas supply inlets 22 are connected to a material gas supply mechanism (not shown) for supplying the process gas to the wafer w.

Further, in the example of FIG. 2, gas discharge outlets 23a are provided at two positions on a bottom surface of the reaction chamber 11. These two gas discharge outlets 23a are respectively connected to a gas discharge mechanism 23 for discharging gas and controlling a pressure inside the reaction chamber 11 to be constant (normal pressure).

Rectifying plates 24 are provided at the upper portion of the reaction chamber 11 so as to provide the process gas supplied from the gas supply inlets 22 onto the wafer w in a rectified state. Further, under the rectifying plates 24, a susceptor 25 that is the retaining member for retaining the wafer w is provided on a ring 26 that is the rotating member. Note that, the retaining member may be an annular holder. The ring 26 is connected to a rotational drive control mechanism 27 configured of a rotary shaft, a motor (not shown) and the like that rotate the wafer w at a predetermined rotational speed.

A disc-shaped heater 28 formed of SiC is for example provided inside the ring 26 to heat the wafer w. Note that, in order to realize uniform heating, a pattern may be provided on the heater 28. As the heater 28, an annular heater for heating a circumferential edge portion of the wafer w may further be used. Further, the heater 28 may include a reflector for realizing efficient heating.

By using the multi-chamber epitaxial growth apparatus configured as above, an Si epitaxial film is formed for example on the Si wafer of φ200 mm.

Firstly, four slices of wafers w are introduced by the IO module 14, and the wafers w are carried respectively into their corresponding reaction chambers A to D via the transfer module 12 using the wafer w conveying robot 13. Then, in each of the reaction chambers A to D, the susceptor 25 having the wafer w mounted thereon is placed on the ring 26.

Next, temperature of the heater 28 is controlled to be at 1500 to 1600° C. so that an in-plane temperature of the wafer w is made to be uniformly at for example 1100° C. Next, the wafer w is rotated for example at 900 rpm by the rotational drive control mechanism 27.

Next, the valves 32a to 32d are turned OFF (cut-off state) and the valve 20b is turned ON (opened state), and the carrier gas inside the carrier gas supply lines 31a to 31d is introduced into the vent line 20c without flowing through the reaction chambers A to D. After the flow rate has been stabilized, firstly the valve 20b is turned OFF (cut-off state) and the valves 32a to 32d are turned ON (opened state) by the carrier gas switching mechanism 33. Then, the carrier gas such as H₂ is supplied respectively to the reaction chambers A to D from the carrier gas supply unit 20a via the carrier gas supply lines 31a to 31d. When the carrier gas is supplied into the reaction chambers A to D from the gas supply inlets 22, it is supplied onto the wafers w in the rectified state via the rectifying plates 24.

Next, under a state in which the carrier gas is being introduced into the respective reaction chambers A to D, the material gas is controlled to be at a predetermined flow rate by the mass flow controller 16a, the valve 19a is turned ON (opened state) and the material gas is introduced into the vent line 19b without flowing through the reaction chambers A to D. Then, after the flow rate has been stabilized, firstly the valve 19a is turned OFF (cut-off state) and the valve 17a is turned ON by the material gas switching mechanism 18, and the material gas is introduced into the reaction chamber A for example for 7.5 seconds. At this occasion, the material gas is mixed with the carrier gas, and the process gas in which dichlorosilane concentration is adjusted to 2.5% for example is supplied onto the wafer w in the rectified state via the rectifying plates 24 at 50 SLM (Standard Litter per Minute).

Then, under the state in which the carrier gas is continuously being supplied to the respective reaction chambers A to D, the valve 17a is turned OFF (cut-off state) and the valve 17b is turned ON by the material gas switching mechanism 18, and the material gas is supplied into the reaction chamber B in a similar manner. At this occasion, only the carrier gas is introduced into the reaction chambers A, C and D from the gas supply inlets 22.

Similarly, the material gas is supplied to the reaction chamber C by turning OFF the valve 17b and turning ON the valve 17c. At this occasion, only the carrier gas is introduced into the reaction chambers A, B and D from the gas supply inlets 22.

Subsequently, the material gas is supplied to the reaction chamber D by turning OFF the valve 17c and turning ON the valve 17d. At this occasion, only the carrier gas is introduced into the reaction chambers A, B and C from the gas supply inlets 22.

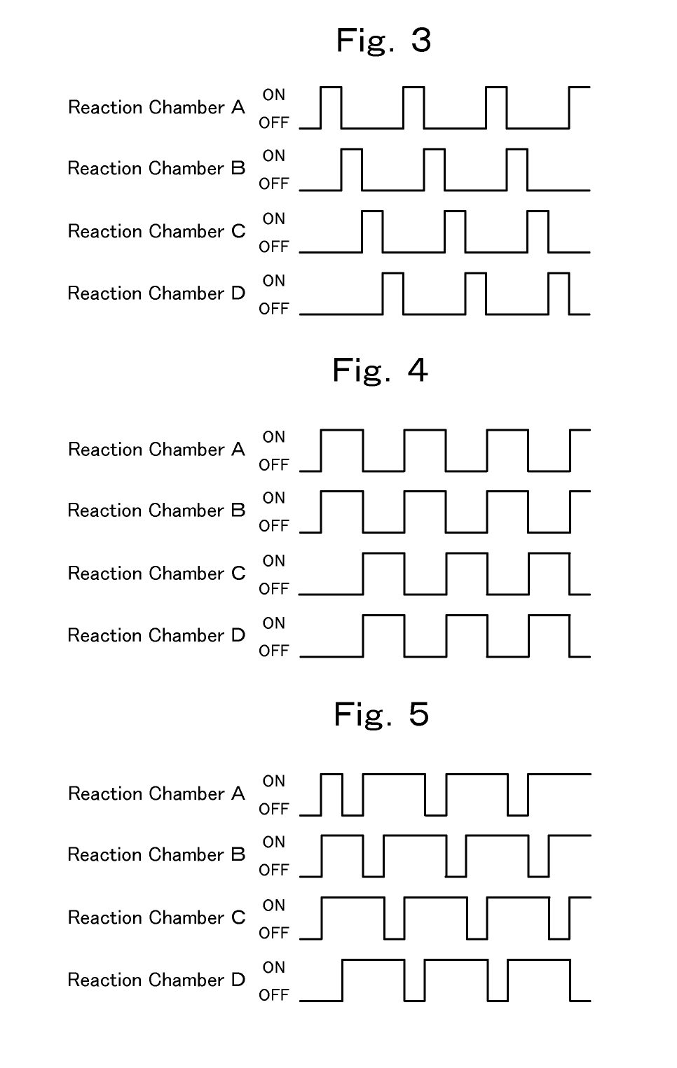

Accordingly, by for example sequentially switching the reaction chamber to which the material gas is supplied every 15 seconds, the process gas including the material gas is supplied intermittently. By controlling as above, as its time chart is shown in FIG. 3, the pulse-epi is performed in the each of the reaction chambers A to D respectively at a time cycle of the material gas being turned ON for 7.5 seconds and OFF for 22.5 seconds. At this occasion, the material gas is supplied to one of the reaction chambers without being ventilated during the OFF period.

On the other hand, an excessive material gas, the process gas including the carrier gas, and a gas such as HCl that is a reaction by-product and the like are discharged downward from an outer periphery of the susceptor 25. Further, these discharged gases are discharged from the gas discharge mechanism 23 via the gas discharge outlets 23a, and the pressure inside the reaction chambers A to D is controlled to be constant (for example, normal pressure).

In this manner, the Si epitaxial film is grown on each wafer w by the pulse-epi being performed. Then, after the Si epitaxial film with a desired thickness for example of 100 μm or more has been formed, each wafer w is carried out from the respective reaction chambers A to D by the IO module 14 via the transfer module 12 by using the wafer w conveying robot 13.

According to the present embodiment, by performing the pulse-epi using the multi-chambers, the material gas is supplied to one of the reaction chambers without being ventilated during the OFF period. Due to this, the use efficiency of the material gas can be improved. Then, by the pulse-epi as mentioned above, the deposition can be performed while discharging HCl that is the reaction product generated by the deposition reaction shown for example by SiHCl₃+H₂→Si+3HCl↑ from above the wafer w. According to this, it becomes possible to maintain satisfactory film quality while suppressing a shift of the deposition reaction toward the left side caused by an increase in HCl concentration, that is, a deceleration of deposition speed. Further, since the flow rate is stabilized by performing the ventilation process for each line prior to supplying the material gas and the carrier gas respectively to the reaction chambers A to D, it is made possible to more accurately perform the control of the supply amounts of the gases to the respective reaction chambers A to D after the ventilation process.

### Second Embodiment

In the present embodiment, a configuration of a multi-chamber epitaxial growth apparatus is similar to the first embodiment. However, it differs from the first embodiment in that the material gas is supplied to a plurality of reaction chambers.

FIG. 4 is a time chart showing a pulse-epi control in the multi-chamber epitaxial growth apparatus of the present embodiment. As shown in FIG. 4, the process gas including the material gas is supplied to the reaction chambers A, B for example for 5 seconds by turning the valves 17a, 17b ON, and only the carrier gas is supplied to the reaction chambers C, D by turning OFF the valves 17c, 17d by the material gas switching mechanism 18.

Next, the process gas including the material gas is supplied to the reaction chambers C, D for example for 10 seconds by turning the valves 17c, 17d ON, and only the carrier gas is supplied to the reaction chambers A, B by turning OFF the valves 17a, 17b.

Accordingly, by for example sequentially switching the reaction chamber to which the material gas is supplied every 10 seconds, the process gas including the material gas is supplied intermittently. By controlling as above, the pulse-epi is performed in each of the reaction chambers A to D respectively at a time cycle of the material gas being turned ON for 10 seconds and OFF for 10 seconds without the material gas being ventilated during the OFF period.

Note that, for example in a similar manner as shown in FIG. 5, after having turned the valves 17a to 17c ON and the valve 17d OFF, sequential switches can be performed by turning the valves 17b to 17d ON and the valve 17a OFF, turning the valves 17c to 17a ON and the valve 17b OFF, and then turning the valves 17d to 17b ON and the valve 17c OFF, and thereby the ratio of the ON/OFF time can be changed.

According to the present embodiment, similar to the first embodiment, by performing the pulse-epi using the multi-chambers, the use efficiency of the material gas can be improved. Further, by the pulse-epi, the deceleration of the deposition speed can be suppressed while maintaining the satisfactory film quality.

### Third Embodiment

In the present embodiment, a configuration of a multi-chamber epitaxial growth apparatus is similar to the first embodiment. However, it differs from the first embodiment in that the supply time of the material gas is controlled to be different for each reaction chamber.

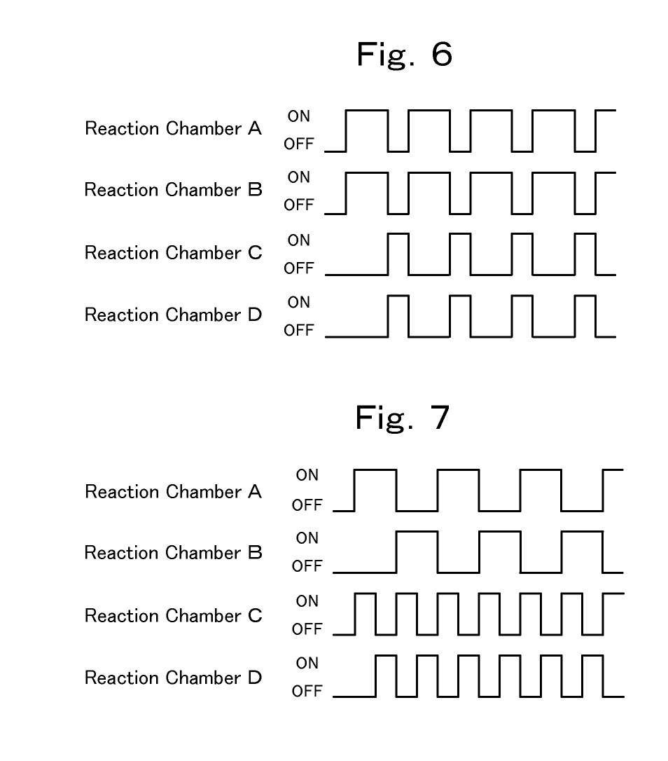

FIG. 6 is a time chart showing a pulse-epi control in the multi-chamber epitaxial growth apparatus of the present embodiment. As shown in FIG. 6, the process gas including the material gas is supplied to the reaction chambers A, B for example for 10 seconds by turning the valves 17a, 17b ON, and only the carrier gas is supplied to the reaction chambers C, D by turning OFF the valves 17c, 17d by the material gas switching mechanism 18.

Next, the process gas including the material gas is supplied to the reaction chambers C, D for example for 5 seconds by turning the valves 17c, 17d ON, and only the carrier gas is supplied to the reaction chambers A, B by turning OFF the valves 17a, 17b.

By so doing, the pulse-epi is performed in the reaction chambers A and B at a time cycle of the material gas being turned ON for 10 seconds and OFF for 5 seconds, and in the reaction chambers C and D at a time cycle of the material gas being turned ON for 5 seconds and OFF for 10 seconds.

According to the present embodiment, similar to the first embodiment, by performing the pulse-epi using the multi-chambers, the use efficiency of the material gas can be improved. Further, by the pulse-epi, the deceleration of the deposition speed can be suppressed while maintaining the satisfactory film quality. Further, since the time during which the material gas is supplied can be changed among the wafers that are concurrently processed, it becomes possible to concurrently form epitaxial films having different thicknesses.

Note that, for example in a similar manner as shown in FIG. 7, the valves are switched every 5 seconds, and after having turned the valves 17a, 17c ON and the valves 17b, 17d OFF, the valves 17a, 17d are turned ON and the valves 17b, 17c are turned OFF. Succeedingly, the valves 17b, 17c are turned ON and the valves 17a, 17d are turned OFF. Further, a sequential switch is performed by turning the valves 17b, 17d ON and turning the valves 17a, 17c OFF. By so doing, since the pulse-epi is performed in the reaction chamber A at a time cycle of the material gas being turned ON for 10 seconds and OFF for 10 seconds, in the reaction chamber B at the time cycle of the material gas being turned ON for 10 seconds and OFF for 10 seconds, and in the reaction chambers C, D at a time cycle of the material gas being turned ON for 5 seconds and OFF for 5 seconds, the ratio of the ON/OFF time can be changed among the concurrently processed wafers.

Accordingly, by changing the ON time during which the material gas is supplied, an overall supplied amount of the material gas can be changed. Due to this, it is possible to concurrently form epitaxial films having three levels of film thicknesses. Further, in a similar manner, it is possible to form the thicknesses of the epitaxial films that are formed on the concurrently processed wafers at four levels or more, and form them all at different thicknesses.

### Fourth Embodiment

In the present embodiment, a configuration of a multi-chamber epitaxial growth apparatus is similar to the first embodiment. However, it differs from the first embodiment in that an Si material gas and a dopant gas are used as the material gas, and a supplied time of the dopant gas is controlled to be different.

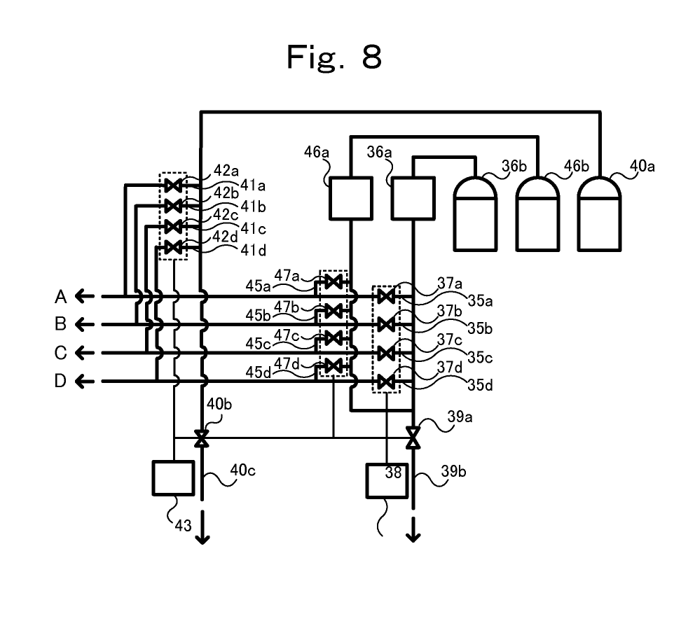

FIG. 8 shows a configuration of gas supply lines of a multi-chamber epitaxial growth apparatus that is the semiconductor manufacturing apparatus of the present embodiment. Note that, configurations other than gas supply lines are similar to FIG. 1.

The respective reaction chambers A to D are, similar to the first embodiment, connected to amass flow controller 36a that controls the flow rate of the Si material gas via Si material gas supply lines 35a to 35d that respectively supply the Si material gas, and an Si material gas supply unit 36b. Valves 37a to 37d are connected to the Si material gas supply lines 35a to 35d, and these valves 37a to 37d are connected to a material gas switching mechanism 38 that controls ON/OFF thereof, and hereby an Si material gas supply mechanism is configured.

Further, the Si material gas supply lines 35a to 35d are, similar to the first embodiment, connected to a vent line 39b having a valve 39a connected to the material gas switching mechanism 38.

Further, the reaction chambers A to D are, similar to the first embodiment, connected respectively to a carrier gas supply unit 40a that is the supply source of the carrier gas via carrier gas supply lines 41a to 41d connected to the Si material gas supply lines 35a to 35d.

Further, valves 42a to 42d for switching the carrier gas supply by opening and closing the valves (ON/OFF) are provided on the carrier gas supply lines 41a to 41d. The valves 42a to 42d are respectively connected to a carrier gas switching mechanism 43 that controls ON/OFF of each valve. A carrier gas supply mechanism is configured of the carrier gas supply unit 40a, the carrier gas supply lines 41a to 41d, the valves 42a to 42d and the carrier gas switching mechanism 43.

Further, a vent line 40c having a valve 40b for the carrier gas ventilation is connected to the carrier gas supply lines 41a to 41d. Note that, the valve 40b is connected to the carrier gas switching mechanism 43 similar to the valves 42a to 42d, and its ON/OFF switching is controlled thereby.

Moreover, the Si material gas supply lines 35a to 35d are further connected to a mass flow controller 46a that controls a flow rate of the dopant gas such as PH₃, B₂H₆ and the like and a dopant gas supply unit 46b. Valves 47a to 47d are connected to the dopant gas supply lines 45a to 45d. Further, these valves 47a to 47d are connected to the material gas switching mechanism 38 that controls ON/OFF thereof, and hereby a dopant gas supply mechanism is configured.

By using the multi-chamber epitaxial growth apparatus configured as above, an Si epitaxial film containing dopants such as P or B is formed for example on the Si wafer w of φ200 mm.

Firstly, similar to the first embodiment, four slices of wafers w are introduced by the IO module 14, and the wafers ware carried respectively into their corresponding reaction chambers A to D via the transfer module 12 using the wafer conveying robot 13. Then, similar to the first embodiment, the wafers w are rotated with their in-plane temperature controlled.

Next, similar to the first embodiment, the carrier gas such as H₂ is supplied in the rectified state onto the wafers w in the respective reaction chambers A to D.

Next, under the state in which the carrier gas is being introduced into the respective reaction chambers A to D, the material gas is controlled to be at a predetermined flow rate by the mass flow controller 36a. Concurrently, the dopant gas is controlled to be at a predetermined flow rate by the mass flow controller 46a, the valve 39a is turned ON, and the gas is introduced into the vent line 39b.

Then, after the flow rates of the Si material gas and the dopant gas have been stabilized, firstly the valve 39a is turned OFF and the valves 37a to 37d on the reaction chamber side are sequentially switched to ON by the material gas switching mechanism 38, and if necessary, the valves 47a to 47d are also sequentially switched to ON. Due to this, process gas in which the carrier gas and/or the dopant gas are mixed and adjusted is supplied onto the wafers w in the rectified state via the rectifying plates 24 at 50 SLM.

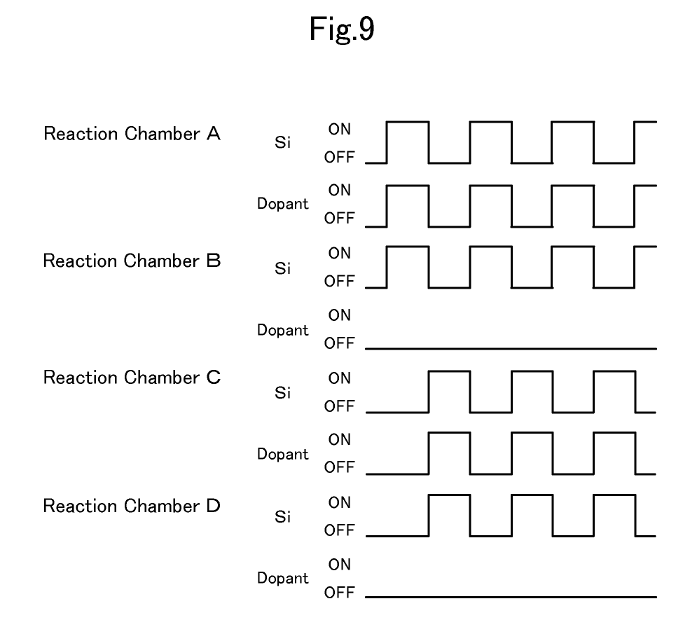

FIG. 9 is a time chart showing a pulse-epi control in the multi-chamber epitaxial growth apparatus of the present embodiment. As shown in FIG. 9, firstly the Si material gas and the dopant gas are introduced to the reaction chamber A and the Si material gas is introduced to the reaction chamber B for example for 7.5 seconds by turning the valves 37a, 37b ON and concurrently the valve 47a ON, and turning the valves 37c, 37d, 47b, 47c and 47d OFF by the material gas switching mechanism 38.

Next, the Si material gas and the dopant gas are introduced to the reaction chamber C and the Si material gas is supplied to the reaction chamber D for example for 7.5 seconds by turning the valves 37c, 37d and the valve 47c ON and turning the valves 37a, 37b and the valves 47a, 47b and 47d OFF.

Accordingly, the pulse-epi is performed by for example sequentially switching the reaction chamber to which the material gas is supplied every 7.5 seconds and sequentially switching the reaction chamber to which the dopant gas is supplied, and supplying the process gas including the material gas, or that to which the dopant gas is further added.

By the pulse-epi being performed as above, Si epitaxial films including the dopants are formed in the reaction chambers A, C, and Si epitaxial films not including the dopants are formed in the reaction chambers B, D, despite their identical film thickness.

According to the present embodiment, similar to the first embodiment, by performing the pulse-epi using the multi-chambers, the use efficiency of the material gas can be improved. Further, by the pulse-epi, the deceleration of the deposition speed can be suppressed while maintaining the satisfactory film quality. Further, since the reaction chamber to which the dopant gas is to be supplied can be selected, it becomes possible to concurrently form epitaxial films with and without the dopants.

Note that, in the present embodiment, it is possible to change an amount of the dopants by changing a supplied time and an overall supplied amount of the dopant gas among the reaction chambers, as are similar to the third embodiment. Further, it is also possible to change the film thickness.

### Fifth Embodiment

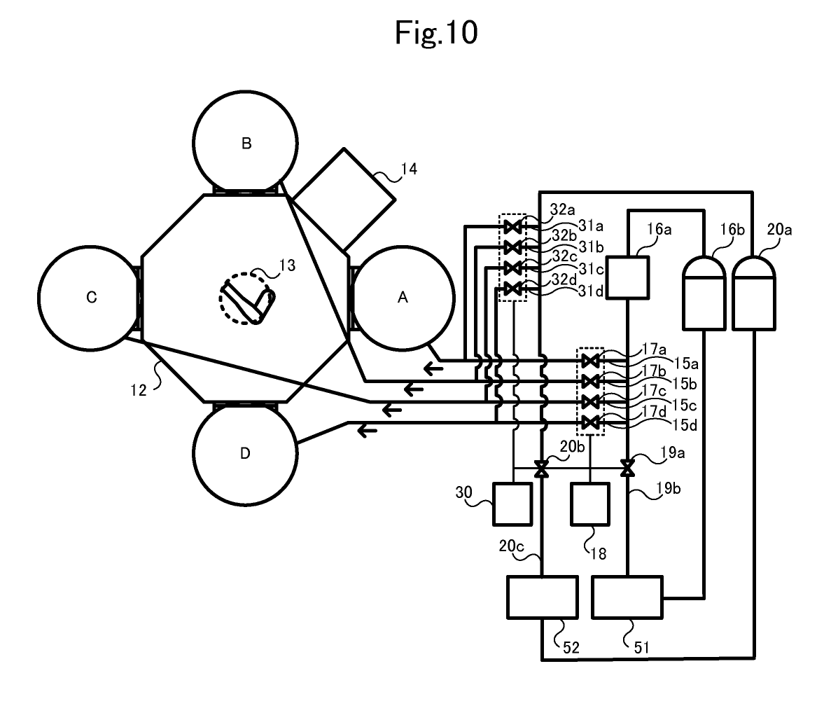

FIG. 10 shows a configuration of a multi-chamber epitaxial growth apparatus that is the semiconductor manufacturing apparatus of the present embodiment. As shown in FIG. 10, in the present embodiment, it differs from the first embodiment in that it includes a material gas storing unit 51 and a carrier gas storing unit 52 in addition to the configuration shown in FIG. 1. The material gas storing unit 51 stores the material gas ventilated from each of the material gas supply lines 15a to 15d via the material gas vent line 19b, and a circulation path of the material gas is formed by the stored material gas being supplied to the material gas supply unit 16b.

Similarly, the carrier gas storing unit 52 stores the carrier gas ventilated from each of the carrier gas supply lines 31a to 31d via the carrier gas vent line 20c, and a circulation path of the carrier gas is formed by the stored carrier gas being supplied to the carrier gas supply unit 20a.

According to such a configuration, by storing the material gas or the carrier gas up to a certain amount and thereafter supplying it by increasing its pressure, recycling the same becomes possible, and the use efficiencies of the material gas and the carrier gas can respectively be improved.

### Sixth Embodiment

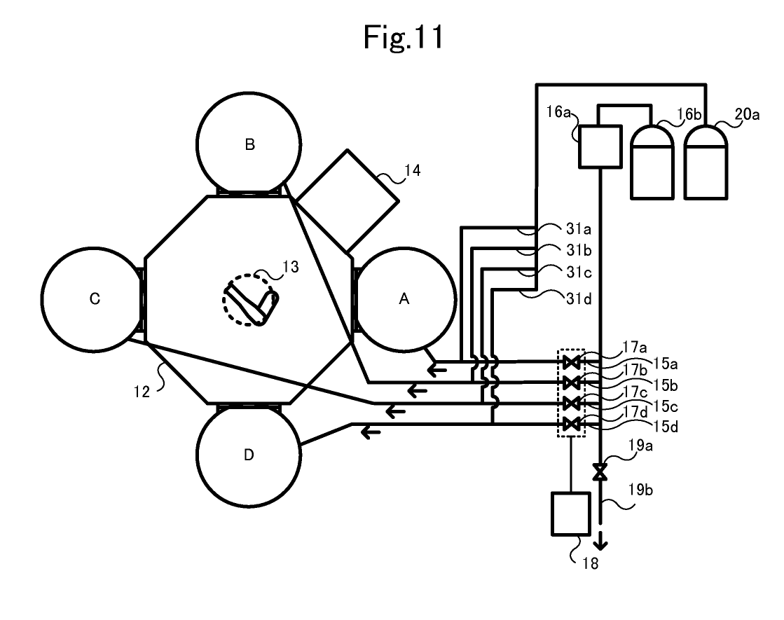

FIG. 11 is a diagram showing a configuration of a multi-chamber epitaxial growth apparatus of the present embodiment. As shown in FIG. 11, compared to the configuration of the apparatus shown in FIG. 1, the configuration of the apparatus of the present embodiment omits the carrier gas switching mechanism. 33 for switching a supply destination of the carrier gas and the valves 32a to 32d for switching thereof, and the vent line 20c for the carrier gas that branches off from the carrier gas supply lines 31a to 31d and the valve 20b for the ventilation thereof.

That is, in the present embodiment, the carrier gas is constantly supplied respectively to the reaction chambers A to D via the carrier gas supply lines 31a to 31d from the carrier gas supply unit 20a. In this case, the adjustment of the pressure inside the reaction chambers A to D can be performed by discharging the process gas including a source gas and the carrier gas and the by-products such as HCl by an operation of the gas discharge mechanism 23.

Further, material cost for the carrier gas having H₂ and the like as its component is generally low compared to the source gas including Si, so a merit of discharging HCl generated above the wafers in the epitaxial deposition process to outside the reaction chambers by supplying the carrier gas and being able to enhance the balance of the deposition reaction shown for example in the following reaction formula toward the right side is greater than a demerit with respect to cost in the case of constantly supplying the carrier gas into the reaction chambers. SiHCl₃+H₂→Si+3HCl↑

Moreover, by having the configuration with the vent line 20c for the carrier gas being omitted, the configuration of the multi-chamber epitaxial growth apparatus is simplified compared to the first embodiment, and thus it further achieves the effect of being able to suppress manufacturing cost of the apparatus.

As described above, although some embodiments were explained, these embodiments have been presented merely as examples. Therefore, the scope of the invention is not limited to the embodiments, and it can be implemented in other embodiments of various kinds. For example, configurations of one embodiment and another embodiment may appropriately be combined.

Further, in the above-described embodiments, although four reaction chambers were provided, simply a plurality of reaction chambers is needed; adaptation thereof is possible by two, three, or five or more chambers.

According to these embodiments, in the semiconductor manufacturing apparatus that forms high quality films such as the epitaxial films on the semiconductor wafers, the productivity can be improved while maintaining the high quality of the epitaxial films, and in addition the use efficiency of the material gas can be improved. Further, in the semiconductor wafers and the semiconductor devices that are formed by going through an element forming process and an element separating process, an achievement of quality improvement, increased productivity, and lowered cost becomes possible.

Especially, it can suitably be used as the epitaxial growth apparatus for forming power semiconductor devices such as power MOSFETs and IGBTs which require growing thick film of 40 μm or more at their N-type base region, P-type base region, insulative isolation region and the like.

Further, in these embodiments, although cases of forming Si monocrystal layers (epitaxial films) have been explained, the present embodiments can alternatively be adapted for forming poly Si layers. Further, for example, an adaptation to depositing films other than Si films, for example SiO₂ films, Si₃N₄ films and the like, and to compound semiconductors, for example GaAs layers, GaAlA or InGaAs and the like, is also possible.

Other embodiments of the invention will be apparent to those skilled in the art from consideration of the specification and practice of the invention disclosed herein. It is intended that the specification and examples be considered as exemplary only, with a true scope and spirit of the invention being indicated by the following claims.

What is claimed is:

1. A semiconductor manufacturing apparatus comprising:
a plurality of reaction chambers into which wafers are introduced and deposition process is performed;
a material gas supply mechanism that includes a plurality of material gas supply lines that respectively supply a material gas to the plurality of reaction chambers and a flow rate control mechanism that controls a flow rate of the marital gas in the material gas supply lines;
a carrier gas supply mechanism that includes a plurality of carrier gas supply lines that respectively supplies a carrier gas into the plurality of reaction chambers; and
a material gas switching mechanism that intermittently opens and closes the plurality of material gas supply lines respectively so that at least one of the plurality of material gas supply lines comes to be in an opened state at a same time, and sequentially switches the reaction chamber to which the material gas is supplied.

2. The semiconductor manufacturing apparatus of claim 1, wherein each of the plurality of reaction chambers further comprises: a retaining member that retains the wafer at a predetermined position inside; a rectifying plate that supplies process gas in a rectified state onto the wafer retained by the retaining member, the process gas including the material gas and the carrier gas supplied to the inside; a heater that heats the wafer retained by the retaining member at a predetermined temperature; and a rotational drive control mechanism that rotates the wafer together with the retaining member at a predetermined rotation speed.

3. The semiconductor manufacturing apparatus of claim 1, wherein the material gas switching mechanism intermittently opens and closes the plurality of material gas supply lines respectively so that at least two of the plurality of material gas supply lines come to be in the opened state at the same time, and sequentially switches the reaction chamber to which the material gas is supplied.

4. The semiconductor manufacturing apparatus of claim 1, wherein the material gas switching mechanism controls a supplied time or an overall supplied amount of the material gas for each of the reaction chambers based on thickness of an epitaxial film to be formed on the wafer.

5. The semiconductor manufacturing apparatus of claim 4, further comprising:
a dopant gas supply mechanism that includes dopant gas supply lines that supply dopant gas to each of the plurality of reaction chambers; and
a dopant gas switching mechanism that switches a supply destination of the dopant gas in accordance with a supply destination of the material gas in the material gas switching mechanism.

6. The semiconductor manufacturing apparatus of claim 4, further comprising:
a material gas vent line that is connected to the material gas supply lines and discharges the material gas without supplying it to the reaction chambers; and
a material gas storing unit that stores the material gas discharged from the material gas vent line.

7. The semiconductor manufacturing apparatus of claim 4, wherein the carrier gas supply mechanism supplies the carrier gas concurrently and continuously to each of the plurality of reaction chambers via the plurality of carrier gas supply lines.

8. The semiconductor manufacturing apparatus of claim 5, wherein the dopant gas switching mechanism controls a supplied time or an overall supplied amount of the dopant gas for each of the reaction chambers based on an amount of dopant to be included in an epitaxial film to be formed on the wafer.

9. The semiconductor manufacturing apparatus of claim 6, further comprising:
a carrier gas vent line that is connected to the carrier gas supply lines and discharges the carrier gas without supplying it to the reaction chambers; and
a carrier gas storing unit that stores the carrier gas discharged from the carrier gas vent line.

10. The semiconductor manufacturing apparatus of claim 3, wherein the material gas switching mechanism controls a supplied time or an overall supplied amount of the material gas for each of the reaction chambers based on thickness of an epitaxial film to be formed on the wafer.

11. The semiconductor manufacturing apparatus of claim 10, further comprising:
a dopant gas supply mechanism that includes dopant gas supply lines that supply dopant gas to each of the plurality of reaction chambers; and
a dopant gas switching mechanism that switches a supply destination of the dopant gas in accordance with a supply destination of the material gas in the material gas switching mechanism.

12. The semiconductor manufacturing apparatus of claim 10, further comprising:
a material gas vent line that is connected to the material gas supply lines and discharges the material gas without supplying it to the reaction chambers; and
a material gas storing unit that stores the material gas discharged from the material gas vent line.

13. The semiconductor manufacturing apparatus of claim 10, wherein the carrier gas supply mechanism supplies the carrier gas concurrently and continuously to each of the plurality of reaction chambers from the plurality of carrier gas supply lines.

14. The semiconductor manufacturing apparatus of claim 11, wherein the dopant gas switching mechanism controls a supplied time or an overall supplied amount of the dopant gas for each of the reaction chambers based on an amount of dopant to be included in an epitaxial film to be formed on the wafer.

15. The semiconductor manufacturing apparatus of claim 12, further comprising:
a carrier gas vent line that is connected to the carrier gas supply lines and discharges the carrier gas without supplying it to the reaction chambers; and
a carrier gas storing unit that stores the carrier gas discharged from the carrier gas vent line.

16. A method of manufacturing a semiconductor device, comprising:
introducing wafers into a plurality of reaction chambers;
retaining the wafers respectively at predetermined positions in the plurality of reaction chambers;
of among a plurality of material gas supply lines that respectively supplies material gas and a plurality of carrier gas supply lines that respectively supplies carrier gas into the plurality of reaction chambers, at least ventilating the material gas from the plurality of material gas supply lines;
intermittently opening and closing the plurality of material gas supply lines respectively so that at least one of the plurality of material gas supply lines comes to be in an opened state at a same time, and sequentially switching the reaction chamber to which the material gas is supplied;
supplying process gas in a rectified state onto the wafers retained inside the reaction chambers, the process gas including the material gas and the carrier gas;
heating the wafers at a predetermined temperature; and
rotating the wafers at a predetermined rotation speed.

17. The method of manufacturing a semiconductor device of claim 16, wherein the plurality of material gas supply lines is intermittently opened and closed respectively so that at least two of the plurality of material gas supply lines come to be in the opened state at the same time, and the reaction chamber to which the material gas is supplied is sequentially changed.

18. The method of manufacturing a semiconductor device of claim 17, wherein a supplied time or an overall supplied amount of the material gas supplied respectively to the plurality of reaction chambers is controlled for each of the reaction chambers based on thickness of epitaxial films to be formed on the wafers.

19. The method of manufacturing a semiconductor device of claim 18, wherein the dopant gas is supplied respectively to the plurality of reaction chambers in accordance with a supply destination of the material gas.

20. The method of manufacturing a semiconductor device of claim 19, wherein a supplied time or an overall supplied amount of the dopant gas is controlled for each of the reaction chambers based on an amount of dopant to be included in the epitaxial film to be formed on the wafers.
